(19) United States
(12) Patent Application Publication
(10) Pub. No.: US 2024/0153766 A1
(43) Pub. Date: May 9, 2024

(54) METHOD OF MANUFACTURING NITROGEN-FACE NITRIDE SEMICONDUCTOR AND NITROGEN-FACE NITRIDE SEMICONDUCTOR DEVICE MANUFACTURED USING THE SAME

(71) Applicant: Tech University of Korea Industry Academic Cooperation Foundation, Siheung (KR)

(72) Inventors: Ok Hyun Nam, Seoul (KR); Min Ho Kim, Incheon (KR); Uiho Choi, Seoul (KR)

(21) Appl. No.: 18/379,082

(22) Filed: Oct. 11, 2023

(30) Foreign Application Priority Data
Nov. 4, 2022 (KR) 10-2022-0146114

(51) Int. Cl. H01L 21/02; H01L 29/20

(52) U.S. Cl. CPC H01L 21/0254; H01L 21/02378; H01L 21/02381; H01L 21/02422; H01L 29/2003; H01L 29/7786

(57) ABSTRACT

A method of manufacturing a nitrogen (N)-face nitride semiconductor and an N-face nitride semiconductor device manufactured using the method are provided. The method includes preparing a substrate, and forming a nitrogen-polarization (N-polar) nitride semiconductor layer on the substrate, using a pulse growth mode. The forming of the N-polar nitride semiconductor layer may include supplying a Group V element precursor, a Group III element precursor, or both in a pulse mode in a vapor deposition process.

### CROSS-REFERENCE TO RELATED APPLICATION

This application claims the benefit of Korean Patent Application No. 10-2022-0146114 filed on Nov. 4, 2022, in the Korean Intellectual Property Office, the entire disclosure of which is incorporated herein by reference for all purposes.

### BACKGROUND

### 1. Field of the Invention

One or more embodiments relate to a method of manufacturing a nitrogen (N)-face nitride semiconductor and an N-face nitride semiconductor device manufactured using the same.

### 2. Description of the Related Art

Recently, many studies have been conducted to develop materials with ultra-wide band gaps, as the reliability of devices increases if a band gap increases. Semiconductors that can operate stably in extreme environments including space radiations or high-temperature environments (>400° C.) such as that on Venus are required in many application fields. Aluminum nitride (AlN) is a promising candidate for such application fields because AlN has the highest band gap (6.2 eV) among nitrides and exhibits excellent thermal conductivity and polarization characteristics.

Due to such characteristics of the AlN, the AlN is used as a good material for electronic and optical devices that may operate in extreme environments. An AlN film is mainly grown on a substrate, such as a silicon (Si) substrate, a silicon carbide (SiC) substrate, or a sapphire substrate. Sapphire substrates are generally used as templates for optical devices that operate in the ultraviolet region.

High-quality AlN templates are used as core materials for ultraviolet light-emitting diodes (UV-LEDs) or high-power and high-frequency semiconductor devices. To date, most research on nitride semiconductors has focused on metal polar faces (Ga, Al, In) having a preferential orientation and grown in the (0001) direction. Recently, a structure grown in the reverse direction ((000-1) direction) has been found to be advantageous in device application fields, and accordingly, nitrogen-polarization (N-polar)(e.g., an N-face or reverse polarization) growth is attracting attention. However, an N-polar thin film layer according to an existing manufacturing method is in the form of mixed metal polarities and has hexagonal hillocks, and it is necessary to develop a manufacturing process to form a high-quality N-polar thin film.

The above description has been possessed or acquired by the inventor(s) in the course of conceiving the present disclosure and is not necessarily an art publicly known before the present application is filed.

### SUMMARY

To solve the above-mentioned problems, using a method of manufacturing a nitrogen (N)-face nitride semiconductor according to embodiments, a nitrogen-polarization (N-polar) (e.g., reverse polarization) Group III nitride semiconductor (e.g., an N-polar aluminum nitride (AlN)) may be grown flat based on growth in a pulse mode in a vapor deposition process, and a high-quality N-polar Group III nitride semiconductor (e.g., an N-polar AlN) may be formed.

According to embodiments, an N-face nitride semiconductor device may be used as a template for a semiconductor device application of an N-polar Group III nitride semiconductor (e.g., an N-polar AlN) through high-quality growth.

According to embodiments, a method of manufacturing an N-face nitride semiconductor includes preparing a substrate, and forming an N-polar nitride semiconductor layer on the substrate using a pulse growth mode. The forming of the N-polar nitride semiconductor layer may include supplying a Group V element precursor, a Group III element precursor, or both in a pulse mode in a vapor deposition process.

According to an embodiment, the substrate may include at least one of silicon, a silicon oxide, a silicon nitride, a silicon carbide, and a combination thereof, and may have a size of 1 inch or greater.

According to an embodiment, the vapor deposition process may include sputtering, vacuum evaporation, atomic layer deposition (ALD), thermal evaporation, metal organic chemical vapor deposition (MOCVD), molecular beam epitaxy (MBE), or hydride vapor phase epitaxy (HVPE).

According to an embodiment, the pulse mode may have a gas flow sequence having a pulse modulation in which each of an ON period and an OFF period is selected from a range of about 1 second to about 100 seconds.

According to an embodiment, the pulse mode may be performed with same or different pulse intervals.

According to an embodiment, the pulse mode may be a continuous pulse mode or a modulated pulse mode.

According to an embodiment, the forming of the N-polar nitride semiconductor layer may include supplying a Group III element precursor in a pulse mode and continuously supplying a Group V element precursor, or may include continuously supplying the Group III element precursor and supplying the Group V element precursor in the pulse mode.

According to an embodiment, the forming of the N-polar nitride semiconductor layer may include supplying a Group V element precursor and a Group III element precursor in pulse modes that are identical to or different from each other.

According to an embodiment, the forming of the N-polar nitride semiconductor layer may be performed at a temperature of about 1000° C. to about 1400° C. for about 10 seconds or greater.

According to an embodiment, the N-face nitride semiconductor may include at least one of AlN, GaAlN, GaN, GaNP, GaNAs, GaNSb, AlGaN, InGaN, BAlGaN, GaAlNP, GaAlNAs, InAlGaN, GaAlNSb, GaInNP, GaInNAs, GaInNSb, and a combination thereof.

According to embodiments, an N-face nitride semiconductor device includes a substrate, and an N-polar nitride semiconductor layer on the substrate. The N-face nitride semiconductor device may be manufactured by at least one or a combination of manufacturing methods according to embodiments of the present disclosure.

According to an embodiment, the N-face nitride semiconductor device may further include a barrier layer of an N-type nitride semiconductor or an N-type nitride semiconductor channel layer on the N-polar nitride semiconductor layer.

According to an embodiment, in the N-polar nitride semiconductor layer, a nitride semiconductor may include at least one of AlN, GaAlN, GaN, GaNP, GaNAs, GaNSb, AlGaN, InGaN, BAlGaN, GaAlNP, GaAlNAs, InAlGaN, GaAlNSb, GaInNP, GaInNAs, GaInNSb, and a combination thereof.

According to an embodiment, a surface of the N-polar nitride semiconductor layer may be free of voids, cracks, or both.

Additional aspects of embodiments will be set forth in part in the description which follows and, in part, will be apparent from the description, or may be learned by practice of the disclosure.

According to an embodiment, using a method of manufacturing an N-face nitride semiconductor, an N-polar Group III nitride semiconductor (e.g., an N-polar AlN) may be grown flat based on growth in a pulse mode in a vapor deposition process, and a high-quality N-polar Group III nitride semiconductor (e.g., an N-polar AlN) may be grown.

According to an embodiment, a method of manufacturing an N-face nitride semiconductor may provide an N-polar Group III nitride semiconductor (e.g., an N-polar AlN) that may be utilized as a material applicable to a next-generation electronic and optical device field (e.g., an optical device field).

According to an embodiment, a method of manufacturing an N-face nitride semiconductor may provide a high-quality N-polar group III nitride semiconductor (e.g., an N-polar AlN) template and an N-polar Group III nitride semiconductor (e.g., an N-polar AlN) device using the template.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 illustrates a process flow of a method of manufacturing a nitrogen (N)-face nitride semiconductor according to embodiments;

FIGS. 2A to 2D illustrate examples of a growth sequence of an N-face nitride semiconductor according to a supply mode of a precursor source in a method of manufacturing an N-face nitride semiconductor according to embodiments;

FIGS. 3A to 3C illustrate surface characteristics according to a growth sequence of an N-face nitride semiconductor according to embodiments; and

FIGS. 4A and 4B illustrate a configuration of an N-face nitride semiconductor device, and an energy bandgap structure, respectively, according to embodiments.

### DETAILED DESCRIPTION

Hereinafter, embodiments will be described in detail with reference to the accompanying drawings. However, various alterations and modifications may be made to the embodiments. Here, the embodiments are not meant to be limited by the descriptions of the present disclosure. The embodiments should be understood to include all changes, equivalents, and replacements within the idea and the technical scope of the disclosure.

The terminology used herein is for the purpose of describing particular embodiments only and is not intended to be limiting. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure.

In addition, the terms such as first, second, A, B, (a), (b) or the like may be used to describe components of the embodiments. Each of these terms is not used to define an essence, order or sequence of a corresponding component but used merely to distinguish the corresponding component from other component(s). It is to be understood that if a component is described as being “connected”, “coupled” or “joined” to another component, the former may be directly “connected”, “coupled”, and “joined” to the latter or “connected”, “coupled”, and “joined” to the latter via another component.

As used herein, “A or B”, “at least one of A and B”, “at least one of A or B”, “A, B or C”, “at least one of A, B and C”, and “at least one of A, B, or C”, each of which may include any one of the items listed together in the corresponding one of the phrases, or all possible combinations thereof.

Components included in an embodiment and components having a common function will be described using the same names in other embodiments. Unless otherwise mentioned, the descriptions on the embodiments may be applicable to the following embodiments and thus, duplicated descriptions will be omitted for conciseness.

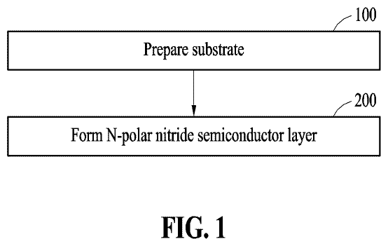

FIG. 1 illustrates a process flow of a method of manufacturing a nitrogen (N)-face nitride semiconductor according to embodiments. Referring to FIG. 1, the method may include step 100 of preparing a substrate, and step 200 of forming a nitrogen-polarization (N-polar) nitride semiconductor layer.

According to an embodiment, step 100 of preparing the substrate may be selected according to use of N-polar nitride semiconductor crystals that may be grown and applied. According to an embodiment, the substrate may include at least one of sapphire (Al₂O₃), silicon (Si), a silicon oxide (SiO₂), a silicon nitride, a silicon carbide (SiC), GaN, GaAs, AlN, and a combination thereof, but is not limited thereto. In some examples, the substrate may be a substrate having a surface on which a Group III nitride semiconductor crystal having good crystallinity may be epitaxially grown and laminated. In some examples, the substrate may be selected from a sapphire substrate, a SiC substrate, and a silicon substrate.

According to an embodiment, the substrate may have a size of about 1 inch or greater; about 2 inches or greater; and about 6 inches or greater, or may have a wafer size of about 12 inches or greater. According to an embodiment, the substrate may be cleaned with plasma or high-temperature gas (e.g., a temperature of about 900° C. or greater).

According to an embodiment, in step 200 of forming the N-polar nitride semiconductor layer, a vapor deposition method, such as a physical vapor deposition or a chemical vapor deposition, may be used. For example, a vapor deposition method, for example, sputtering, vacuum evaporation, atomic layer deposition (ALD), thermal evaporation, metal organic chemical vapor deposition (MOCVD), molecular beam epitaxy (MBE), hydride vapor phase epitaxy (HVPE), and the like, may be used to form the N-polar nitride semiconductor layer, however, embodiments are not limited thereto. In some examples, a Group III-V nitride semiconductor may be formed by reacting a precursor gas containing a Group V element and a Group III element precursor through a plasma activation. In some examples, MOCVD may be used.

According to an embodiment, in step 200 of forming the N-polar nitride semiconductor layer, an N-polar nitride semiconductor may be grown at a temperature of about 1000° C. or greater; about 1100° C. or greater; about 1200° C. to about 1400° C.; or about 1200° C. to about 1300° C. for about 10 seconds or greater; about 100 seconds or greater; about 200 seconds or greater; about 300 seconds or greater; about 500 seconds or greater; about 800 seconds or greater; or about 1000 seconds or greater. In some examples, step 200 may be performed at a pressure of about 10 hectopascals (hPa) to about 500 hPa. In some examples, step 200 may be performed at a pressure of about 10 hPa or less; about 5 hPa or less; about 1 hPa or less; about 0.1 hPa or less; or about 0.01 hPa or less; or in a range of about 0.001 hPa to about 1e-7 hPa. In some examples, desirably, step 200 may be performed at a pressure of about 50 hPa to about 500 hPa. In some embodiments, a ratio (%) of horizontal growth to vertical growth in the N-polar nitride semiconductor layer may be less than 50; in a range of greater than 50 to 1:99; in a range of 30:70 to 5:95; in a range of 20:80 to 5:95; in a range of 10:90 to 1:99; or about 100% indicating the vertical growth. In some examples, growth of a high-quality N-polar nitride semiconductor (e.g., N-polar AlN) thin film may be promoted. In some examples, the N-polar nitride semiconductor layer may be free of cracks.

According to an embodiment, in step 200 of forming the N-polar nitride semiconductor layer, a molar ratio of a Group V precursor to a Group III precursor may be about 100 or greater; about 200 or greater; about 500 or greater; about 1000 or greater; about 1500 or greater; about 2000 or greater; about 4000 or greater; about 5000 or greater; about 6000 or greater; about 7000 or greater; or in a range of about 200 to about 1000; in a range of about 250 to about 450; in a range of about 250 to about 350; in a range of about 1000 to about 7000; in a range of about 3000 to about 7000; in a range of about 4000 to about 7000; in a range of about 5000 to about 6500; or about 6000. In some examples, a high-quality N-face nitride semiconductor layer may be formed within the above-described range.

According to an embodiment, in step 200 of forming the N-polar nitride semiconductor layer, a flow rate of each of the Group V precursor and the Group III precursor may be about 20 standard cubic centimeters per minute (sccm) or greater; about 25 sccm or greater; about 30 sccm or greater; about 50 sccm or greater; about 100 sccm or greater; or in a range of about 150 sccm to about 250 sccm.

According to an embodiment, the N-polar nitride semiconductor layer may be formed to a desired thickness, and may have a thickness of, for example, about 1 nm or greater; about 50 nm or greater; about 100 nm or greater; about 500 nm or greater; about 1 μm or greater; about 5 μm or greater; about 10 μm or greater; about 20 μm or greater; or about 1 nm to about 10 μm.

According to an embodiment, in step 200 of forming the N-polar nitride semiconductor layer, a pulse growth mode may be used to form the N-polar nitride semiconductor layer on the substrate. In a process of growing the N-polar nitride semiconductor, a deposition gas (e.g., a raw material gas) (e.g., a precursor gas) may be supplied in a pulse mode in which supply (ON) and cut-off (OFF) are periodically repeated, to grow the N-polar nitride semiconductor.

According to an embodiment, in step 200 of forming the N-polar nitride semiconductor layer, a Group V element precursor (e.g., a nitrogen element precursor), a Group III element precursor, or both may be supplied in the pulse mode in a vapor deposition process, so that injection may be controlled. In some examples, using the pulse mode, it may be possible to enable the N-polar nitride semiconductor to be grown flat and realize high-quality growth. In some examples, a high-quality N-polar Group III nitride semiconductor (e.g., an N-polar AlN) template may be manufactured through pulse growth in a vapor deposition chamber (e.g., an MOCVD chamber) even without an external process. In some examples, all materials applicable to forming an N-polar nitride semiconductor may be applied to the Group III element precursor without a limitation, and the Group III element precursor may include, for example, trimethylaluminum (TMA), trimethylgallinum (TMG), trimethylindium (TMI), etc., but is limited thereto. In some examples, a precursor including an element that may be added may be included in addition to the Group III element precursor. In some examples, the Group V element precursor may be a nitrogen element precursor and may further include a Group V element according to an elementary composition of a nitride semiconductor.

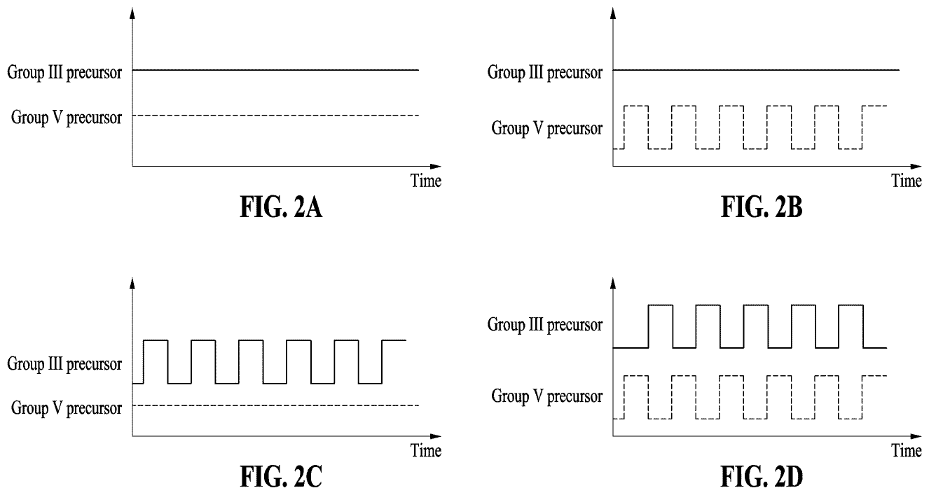

Is According to an embodiment. FIGS. 2A to 2D illustrate growth sequences of a Group III nitride semiconductor according to a supply mode of a source of a precursor in a method of manufacturing an N-face nitride semiconductor according to embodiments. In FIG. 2A, a Group V element precursor and a Group III element precursor may be continuously supplied instead of utilizing a pulse mode, and accordingly, metal polarities may be mixed or a hillock and the like may occur. In FIG. 2B, a Group V element precursor may be supplied in a pulsed mode and a Group III element precursor may be continuously supplied instead of utilizing a pulse mode. In FIG. 2C, a Group V element precursor may be continuously supplied instead of utilizing a pulse mode and a Group III element precursor may be supplied in a pulse mode. In FIG. 2D, both a Group V element precursor and a Group III element precursor may be supplied in a pulse mode so that ON and OFF periods of a pulse of the Group V element precursor may intersect with ON and OFF periods of a pulse of the Group III element precursor.

According to an embodiment, the pulse mode may have a gas flow sequence with a pulse modulation within an ON period of about 1 second to about 100 seconds and an OFF period of about 1 second to about 100 seconds. In some examples, each of the ON period and the OFF period in the pulse mode may be in a range of about 1 second to about 100 seconds; about 1 second to about 80 seconds; about 1 second to about 60 seconds; about 1 second to about 50 seconds; about 1 second to about 40 seconds; about 1 second to about 30 seconds; about 1 second to about 20 seconds; about 1 second to about 10 seconds; about 2 seconds to about 10 seconds; about 2 seconds to about 8 seconds; about 3 seconds to about 6 seconds; or about 3 seconds to about 5 seconds. In some examples, the ON period and the OFF period in the pulse mode may be identical to or different from each other. In some examples, as the pulse mode, a continuous pulse mode or a modulated pulse mode may be applied. The continuous pulse mode may be performed with the same pulse (e.g., the same interval D in FIGS. 2A to 2D) (e.g., the same duty cycle). The modulated pulse mode may be performed with two or more different pulses (e.g., different duty cycles or pulse intervals (periods)). For example, the two or more different pulses may differ in at least one of a pulse interval (e.g., a period D of FIGS. 2A to 2D), a height and a shape of a pulse, and a duty cycle. In some examples, the pulse mode may be performed with a duty cycle in which identical or different pulse intervals (e.g., a sum of ON and OFF periods) are combined. Here, the duty cycle may be “(T_{high}/period (D in FIGS. 2A to 2D))×100.”

According to an embodiment, in the pulse mode, the Group V element precursor and the Group III element precursor may be modulated so that ON and OFF periods of the Group V element precursor may intersect with ON and OFF periods of the Group III element precursor.

According to an embodiment, in step 200 of forming the N-polar nitride semiconductor layer, the Group III element precursor may be supplied in a pulse mode and the Group V element precursor may be continuously supplied.

According to an embodiment, the Group V element precursor may be continuously supplied and the Group V element precursor may be supplied in the pulse mode. In some examples, in step 200 of forming the N-polar nitride semiconductor layer, the Group V element precursor and the Group III element precursor may be supplied in pulse modes that are identical to or different from each other.

According to an embodiment, a thin film of the N-polar nitride semiconductor may include a single crystalline Group III nitride semiconductor structure. For example, the thin film may include a polycrystallinity of about 5% or less, a polycrystallinity of about 2% or less, a polycrystallinity of about 1% or less, a polycrystallinity of about 0.5% or less, or a polycrystallinity of about 0%. In some examples, the thin film may not include a polycrystallinity. In some examples, the quality of the N-polar nitride semiconductor layer may be increased by lowering macroscopic defects such as a polycrystallinity.

According to an embodiment, the N-polar nitride semiconductor layer may include a Group III nitride semiconductor material, may include a Group III element selected from Al, Ga, In, and a combination thereof, and may further include, if necessary, an element, for example, Ge, Si, Mg, Ca, Cu, Zn, Be, P, Sb, S, Se, Te, and As. In some examples, a Group V element may be added. For example, the N-polar nitride semiconductor layer may be AlN, GaAlN, GaN, GaNP, GaNAs, GaNSb, AlGaN, InGaN, BAlGaN, GaAlNP, GaAlNAs, InAlGaN, GaAlNSb, GaInNP, GaInNAs, GaInNSb, and the like, but is not limited thereto. In some examples, the Group III nitride semiconductor material may be selected from AlN, GaN, and GaAlN.

According to an embodiment, an N-face nitride semiconductor material (e.g., a thin film, a film, or a sheet) or an N-face nitride semiconductor device may be provided by the method according to the present disclosure. According to an embodiment, the N-face nitride semiconductor material (e.g., a thin film, a film, or a sheet) or the N-face nitride semiconductor device may include a substrate, and an N-polar nitride semiconductor layer on the substrate. The substrate and the N-polar nitride semiconductor layer are the same as those described in the method according to the present disclosure. According to an embodiment, the N-face nitride semiconductor material (e.g., a thin film, a film, or a sheet) or the N-face nitride semiconductor device may include a high-quality N-polar nitride semiconductor layer that is grown to be uniform and flat.

According to an embodiment, a surface of the N-polar nitride semiconductor layer may be free of voids, cracks, or both.

According to an embodiment the N-face nitride semiconductor device may include a barrier layer of an N-type nitride semiconductor, an N-type nitride semiconductor channel layer, or both on the N-polar nitride semiconductor layer, and may further include an electrode layer (e.g., a metal electrode layer, a gate electrode, a source electrode, and a drain electrode) on the barrier layer and the N-type nitride semiconductor channel layer. In an example, the N-face nitride semiconductor device may be a substrate/N-type nitride semiconductor layer/barrier layer (N—AlGaN barrier (A˜32%))/channel layer (N—GaN channel)/electrode. In another example, the N-face nitride semiconductor device may be a substrate/N-type nitride semiconductor layer/channel layer (N—GaN channel)/electrode. A 2DEG (two-dimensional electron gas) may be included in a thin channel layer (N—GaN channel).

According to an embodiment, the N-face nitride semiconductor device may provide a short channel suppression effect in comparison to existing metal polarities, a carrier confinement effect through a low ohmic contact resistance and a spontaneous back-barrier, and an effect of suppressing DIBL. In addition, it may be possible to expand the range of available electronic devices by improving the scalability of devices. For example, this may be an N-polar ill-nitride-based a high electron mobility transistor (HEMT) epi that realizes an ultra-high power density or ultra-high frequency.

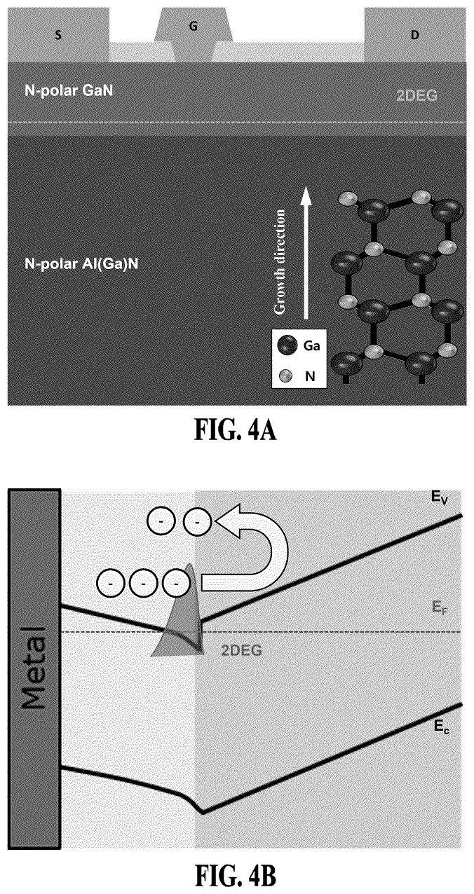

Referring to FIGS. 4A and 4B, a structure having N-polar Al(Ga)N/N-polar GaN in an N-polar III nitride-based HEMT epi, and an energy band structure thereof are shown. In FIGS. 4A and 4B, an effect of suppressing a short channel effect may increase electron confinement under a presence of an AlGaN back-barrier (a barrier layer is not shown in FIGS. 4A and 4B), and may provide a subthreshold with improved low output conductance. In addition, when GaN (with small E_{g}) is present in a surface material, metal and a semiconductor may be easily coupled. In addition, by generating a 2DEG in thin GaN, a gate length may be reduced, so that a gate-channel capacitance may be reduced and a high transconductance may be achieved.

FIG. 4B illustrates an energy band structure of an AlN-based HEMT into which a polarization charge relaxation layer is inserted, and an AlGaN graded layer (2EDG) is inserted between GaN and AlN so that negative polarization charges may be relaxed, and as a result, a hole concentration may be reduced.

Hereinafter, the present invention will be described in detail based on examples. However, the following examples are only for illustrating the present disclosure, and the present disclosure is not limited to the following examples.

### Examples

An AlN thin film having an N face was grown using an HT-MOCVD (Top Engineering, PHAETHON 100U) reactor. Trimethylaluminum (TMA) was used as a Group III precursor, and ammonia (NH₃, 99.999%) was used as a Group V precursor. Hydrogen (H₂) was used as a carrier gas. During a deposition of AlN, the pressure was 40 hPa, the flow rate of TMA was 26 sccm, and the ratio of Groups V/III was 6000. A substrate was a Si face of the on-axis semi-insulating 4H-SiC (0001) (Cree Inc (Durham, NC, USA)). Prior to the deposition of the AlN layer, a SiC substrate was thermally cleaned in a high-temperature H₂ atmosphere. Scanning electron microscope (SEM) images are shown based on a gas flow sequence with a pulse modulation of TMA and NH₃ (on=1 second to 100 seconds and off=1 second to 100 seconds) on the upper right portion.

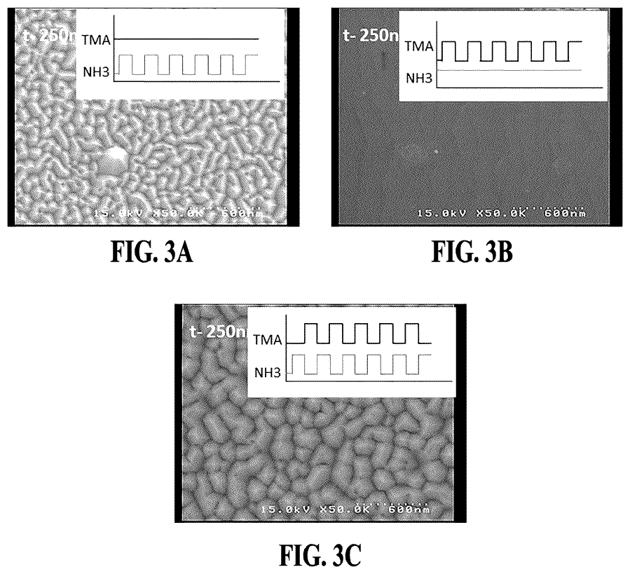

FIGS. 3A to 3C illustrate examples of a surface of a thin film according to a pulse process. As shown in FIGS. 3A to 3C, surface characteristics of an N-face nitride semiconductor may be confirmed according to the pulse process.

In the present disclosure, an N-polar Group III nitride semiconductor may be grown flat by controlling injection of a precursor source, desirably, a Group III precursor source (e.g., TMA) using a pulse method, and a high-quality N-polar Group III nitride semiconductor (e.g., an N-polar AlN) template for electronic devices may be manufactured through high-quality growth.

While the embodiments are described with reference to drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order and/or if components in a described system, architecture, device, or circuit are combined in a different manner and/or replaced or supplemented by other components or their equivalents.

Therefore, other implementations, other embodiments, and equivalents to the claims are also within the scope of the following claims.

What is claimed is:

1. A method of manufacturing a nitrogen (N)-face nitride semiconductor, the method comprising:
preparing a substrate; and
forming a nitrogen-polarization (N-polar) nitride semiconductor layer on the substrate, using a pulse growth mode,
wherein the forming of the N-polar nitride semiconductor layer comprises supplying a Group V element precursor, a Group III element precursor, or both in a pulse mode in a vapor deposition process.

2. The method of claim 1, wherein
the substrate comprises at least one selected from a group consisting of silicon, a silicon oxide, a silicon nitride, a silicon carbide, and a combination thereof, and
the substrate has a size of about 1 inch or greater.

3. The method of claim 1, wherein the vapor deposition process comprises sputtering, vacuum evaporation, atomic layer deposition (ALD), thermal evaporation, metal organic chemical vapor deposition (MOCVD), molecular beam epitaxy (MBE), or hydride vapor phase epitaxy (HVPE).

4. The method of claim 1, wherein the pulse mode has a gas flow sequence with a pulse modulation in which each of an ON period and an OFF period is selected from a range of about 1 second to about 100 seconds.

5. The method of claim 1, wherein the pulse mode is performed with same or different pulse intervals.

6. The method of claim 1, wherein the pulse mode is a continuous pulse mode or a modulated pulse mode.

7. The method of claim 1, wherein the forming of the N-polar nitride semiconductor layer comprises supplying a Group III element precursor in a pulse mode and continuously supplying a Group V element precursor.

8. The method of claim 1, wherein the forming of the N-polar nitride semiconductor layer comprises continuously supplying a Group III element precursor and supplying a Group V element precursor in a pulse mode.

9. The method of claim 1, wherein the forming of the N-polar nitride semiconductor layer comprises supplying a Group V element precursor and a Group III element precursor in pulse modes that are identical to or different from each other.

10. The method of claim 1, wherein the forming of the N-polar nitride semiconductor layer is performed at a temperature of about 1000° C. to about 1400° C. for about 10 seconds or greater.

11. The method of claim 1, wherein the N-face nitride semiconductor comprises at least one selected from a group consisting of AlN, GaAlN, GaN, GaNP, GaNAs, GaNSb, AlGaN, InGaN, BAlGaN, GaAlNP, GaAlNAs, InAlGaN, GaAlNSb, GaInNP, GaInNAs, GaInNSb, and a combination thereof.

12. A nitrogen (N)-face nitride semiconductor device manufactured by the method of claim 1, the N-face nitride semiconductor device comprising:
a substrate; and
a nitrogen-polarization (N-polar) nitride semiconductor layer on the substrate.

13. The N-face nitride semiconductor device of claim 12, further comprising:
a barrier layer of an N-type nitride semiconductor or an N-type nitride semiconductor channel layer on the N-polar nitride semiconductor layer.

14. The N-face nitride semiconductor device of claim 12, wherein a surface of the N-polar nitride semiconductor layer is free of voids, cracks, or both.
